(19) United States
(12) Patent Application Publication
(10) Pub. No.: US 2026/0173343 A1
(43) Pub. Date: Jun. 18, 2026

(54) ORGANOMETALLIC COMPOUND AND METHOD OF MANUFACTURING SEMICONDUCTOR DEVICE USING THE SAME

(71) Applicant: Samsung Electronics Co., Ltd., Suwon-si (KR)

(72) Inventors: Geunho Choi, Suwon-si (KR); Soonhyeok Hong, Suwon-si (KR); Beomsoon Park, Suwon-si (KR); Jaewoon Kim, Suwon-si (KR); Gyuhee Park, Suwon-si (KR); Jeongwoo Lee, Suwon-si (KR); Younjoung Cho, Suwon-si (KR); Dabon Lee, Suwon-si (KR)

(73) Assignee: Korea Advanced Institute of Science and Technology, Daejeon (KR)

(21) Appl. No.: 19/331,514

(22) Filed: Sep. 17, 2025

(30) Foreign Application Priority Data
Dec. 17, 2024 (KR) 10-2024-0189095

(51) Int. Cl. H10B 12/00; C07F 15/00; C23C 16/455

(52) U.S. Cl. CPC H10B 12/033; C07F 15/0033; C23C 16/45553

(57) ABSTRACT

An organometallic compound represented by Formula 1 below is presented:

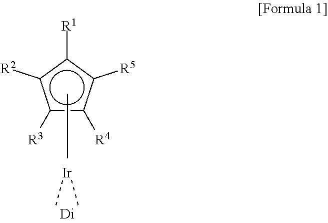

wherein, in Formula 1, R¹, R², R³, R⁴, and R⁵ are each independently a substituent including a heteroatom, hydrogen, an alkyl group having 1 to 10 carbon atoms, an alkenyl group having 2 to 10 carbon atoms, or an alkynyl group having 2 to 10 carbon atoms, and Di is a diene-based hydrocarbon, provided that a case where R¹, R², R³, R⁴, and R⁵ are all hydrogen or methyl groups is excluded or a case where one of R¹, R², R³, R⁴, and R⁵ is an alkyl group and the remaining ones are hydrogen is excluded.

### CROSS-REFERENCE TO RELATED APPLICATION

This application is based on and claims priority under 35 U.S.C. § 119 to Korean Patent Application No. 10-2024-0189095, filed on Dec. 17, 2024, in the Korean Intellectual Property Office, the disclosure of which is incorporated by reference herein in its entirety.

### BACKGROUND

Due to the development of electronic technologies, downscaling of semiconductor devices has been progressing rapidly in recent years, and as a result, patterns that configure electronic devices are becoming smaller. Accordingly, it is desired to develop a raw material compound for forming a metal-containing film that can provide excellent embedding characteristics and excellent step coverage characteristics when forming a metal-containing film required for the manufacture of semiconductor devices, and is easy to handle, thus being advantageous in terms of process stability and mass productivity.

### SUMMARY

An organometallic compound is presented and a method of manufacturing a semiconductor device using the same, and more particularly, to an organometallic compound containing iridium as a metal and a method of manufacturing a semiconductor device using the same.

An organometallic compound is presented that can be used as a raw material compound capable of providing excellent thermal stability, process stability, and mass productivity when forming a metal-containing film necessary for manufacturing a semiconductor device.

A method is presented of manufacturing a semiconductor device capable of providing desired electrical characteristics by forming a metal-containing film of excellent quality using a metal-containing raw material compound capable of providing excellent process stability and mass productivity.

There is provided an organometallic compound represented by Formula 1 below:

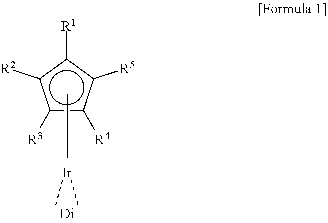

wherein, in Formula 1, R¹, R², R³, R⁴, and R⁵ are each independently a substituent including a heteroatom, hydrogen, an alkyl group having 1 to 10 carbon atoms, an alkenyl group having 2 to 10 carbon atoms, or an alkynyl group having 2 to 10 carbon atoms, and Di is a diene-based hydrocarbon, provided that a case where R¹, R², R³, R⁴, and R⁵ are all hydrogen or methyl groups or a case where only one of R¹, R², R³, R⁴, and R⁵ is an alkyl group and the remaining ones except for any one of R¹, R², R³, R⁴, and R⁵ are hydrogen is excluded.

There is provided a method of manufacturing a semiconductor device, the method including: forming a metal-containing film on a substrate using the organometallic compound represented by Formula 1 above.

There is provided a method of manufacturing a semiconductor device, the method including: forming an insulating pattern in a first region on a substrate, forming a first metal-containing film in a second region on the substrate, forming a second metal-containing film covering the first metal-containing film, and forming a third metal-containing film covering the second metal-containing film, wherein at least one of the first metal-containing film, the third metal-containing film, an interface between the first metal-containing film and the second metal-containing film, and an interface between the second metal-containing film and the third metal-containing film is formed using the organometallic compound of Formula 1 above.

### BRIEF DESCRIPTION OF THE DRAWINGS

Implementations will be more clearly understood from the following detailed description taken in conjunction with the accompanying drawings in which:

FIG. 1 is a flowchart illustrating a method of manufacturing a semiconductor device, according to some implementations;

FIG. 2 is a flowchart specifically illustrating a method for forming a metal-containing film according to the method of manufacturing a semiconductor device according to some implementations; and

FIGS. 3 to 12 are cross-sectional views illustrating a process sequence for explaining a method of manufacturing a semiconductor device according to implementations.

### DETAILED DESCRIPTION

Hereinafter, implementations will be described in detail with reference to the attached drawings. However, the drawings attached to this specification are intended to explain implementations but the disclosure is not limited thereto. The same reference symbols are used for identical components in the drawings, and duplicate descriptions of these are omitted.

An organometallic compound according to some implementations may be represented by Formula 1 below:

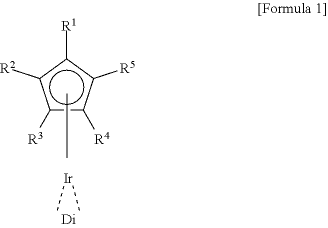

wherein, in Formula 1, R¹, R², R³, R⁴, and R⁵ are each independently a substituent including a heteroatom, hydrogen, an alkyl group having 1 to 10 carbon atoms, an alkenyl group having 2 to 10 carbon atoms, or an alkynyl group having 2 to 10 carbon atoms, and Di is a diene-based hydrocarbon, provided that a case where R¹, R², R³, R⁴, and R⁵ are all hydrogen or methyl groups or a case where only one of R¹, R², R³, R⁴, and R⁵ is an alkyl group and the remaining ones except for any one of R¹, R², R³, R⁴, and R⁵ are hydrogen is excluded. An organometallic compound according to some implementations may be represented by Formula 2 below:

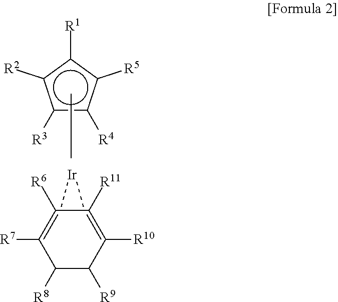

wherein, in Formula 2, R¹, R², R³, R⁴, and R⁵ are each independently a substituent including a heteroatom, hydrogen, an alkyl group having 1 to 10 carbon atoms, an alkenyl group having 2 to 10 carbon atoms, or an alkynyl group having 2 to 10 carbon atoms,
provided that a case where R¹, R², R³, R⁴, and R⁵ are all hydrogen or methyl groups or a case where only one of R¹, R², R³, R⁴, and R⁵ is an alkyl group and the remaining ones except for any one of R¹, R², R³, R⁴, and R⁵ are hydrogen is excluded, and
R⁶, R⁷, R⁸, R⁹, R¹⁰, and R¹¹ are each independently hydrogen, an alkyl group having 1 to 10 carbon atoms, an acyl group having 1 to 10 carbon atoms, or an alkoxy group having 1 to 10 carbon atoms.

In some implementations, the heteroatom may be, for example, Si, O, N, P, or S. For example, the substituent including the heteroatom may include a trimethylsilyl group, a triethylsilyl group, a triisopropylsilyl group, a dimethylisopropylsilyl group, a diethylisopropylsilyl group, a dimethyltetrasilyl group, a t-butyldimethylsilyl group, a methoxy group, an ethoxy group, and the like.

In some implementations, in Formula 2, any one of R¹, R², R³, R⁴, and R⁵ may be a substituent including a heteroatom, and the remaining ones except for any one of R¹, R², R³, R⁴, and R⁵ may each independently be hydrogen.

In some implementations, in Formula 2, at least two of R¹, R², R³, R⁴, and R⁵ may be an alkyl group having 1 to 10 carbon atoms, an alkenyl group having 2 to 10 carbon atoms, or an alkynyl group having 2 to 10 carbon atoms, and the remaining ones except for at least two of R¹, R², R³, R⁴, and R⁵ may be hydrogen, provided that a case where each of R¹, R², R³, R⁴, and R⁵ is a methyl group may be excluded.

In some implementations, in Formula 2, any one of R¹, R², R³, R⁴, and R⁵ may be a substituent including a heteroatom, and the remaining ones except for any one of R¹, R², R³, R⁴, and R⁵ may each independently be an alkyl group having 1 to 10 carbon atoms, an alkenyl group having 2 to 10 carbon atoms, or an alkynyl group having 2 to 10 carbon atoms.

In some implementations, in Formula 2, at least two of R¹, R², R³, R⁴, and R⁵ may be substituents including a heteroatom, and the remaining ones except for at least two of R¹, R², R³, R⁴, and R⁵ may each independently be hydrogen, an alkyl group having 1 to 10 carbon atoms, an alkenyl group having 2 to 10 carbon atoms, or an alkynyl group having 2 to 10 carbon atoms.

An organometallic compound according to some implementations may be represented by Formula 3 below:

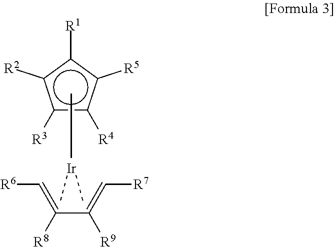

wherein, in Formula 3, R¹, R², R³, R⁴, and R⁵ are each independently a substituent including a heteroatom, hydrogen, an alkyl group having 1 to 10 carbon atoms, an alkenyl group having 2 to 10 carbon atoms, or an alkynyl group having 2 to 10 carbon atoms,
provided that a case where R¹, R², R³, R⁴, and R⁵ are all hydrogen or methyl groups or a case where only one of R¹, R², R³, R⁴, and R⁵ is an alkyl group and the remaining ones except for any one of R¹, R², R³, R⁴, and R⁵ are hydrogen is excluded, and
R⁶, R⁷, R⁸, and R⁹ are each independently hydrogen, an alkyl group having 1 to 10 carbon atoms, an acyl group having 1 to 10 carbon atoms, or an alkoxy group having 1 to 10 carbon atoms.

In some implementations, the heteroatom may be, for example, Si, O, N, P, or S. For example, the substituent including the heteroatom may include a trimethylsilyl group, a triethylsilyl group, a triisopropylsilyl group, a dimethylisopropylsilyl group, a diethylisopropylsilyl group, a dimethyltetrasilyl group, a t-butyldimethylsilyl group, a methoxy group, an ethoxy group, and the like.

In some implementations, in Formula 3, any one of R¹, R², R³, R⁴, and R⁵ may be a substituent including a heteroatom, and the remaining ones except for any one of R¹, R², R³, R⁴, and R⁵ may each independently be hydrogen.

In some implementations, in Formula 3, at least two of R¹, R², R³, R⁴, and R⁵ may be alkyl groups having 1 to 10 carbon atoms, alkenyl groups having 2 to 10 carbon atoms, or alkynyl groups having 2 to 10 carbon atoms, and the remaining ones except for at least two of R¹, R², R³, R⁴, and R⁵ may be hydrogen, provided that a case where each of R¹, R², R³, R⁴, and R⁵ is a methyl group may be excluded.

In some implementations, in Formula 3, any one of R¹, R², R³, R⁴, and R⁵ may be a substituent including a heteroatom, and the remaining ones except for any one of R¹, R², R³, R⁴, and R⁵ may each independently be an alkyl group having 1 to 10 carbon atoms, an alkenyl group having 2 to 10 carbon atoms, or an alkynyl group having 2 to 10 carbon atoms.

In some implementations, in Formula 3, at least two of R¹, R², R³, R⁴, and R⁵ may be substituents including a heteroatom, and the remaining ones except for at least two of R¹, R², R³, R⁴, and R⁵ may each independently be hydrogen, an alkyl group having 1 to 10 carbon atoms, an alkenyl group having 2 to 10 carbon atoms, or an alkynyl group having 2 to 10 carbon atoms.

Specific examples of organometallic compounds according to some implementations may be represented by Formulas below. However, specific examples of organometallic compounds according to some implementations are not limited to those exemplified below.

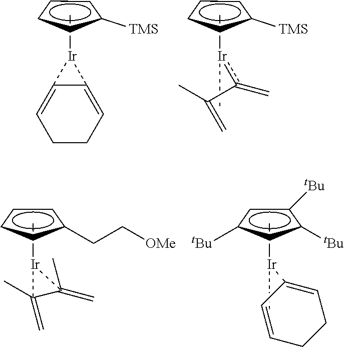

In Formulas above, TMS may refer to a trimethylsilyl group, and tBu may refer to a tert-butyl group.

The organometallic compound according to some implementations may include a cyclopentadiene having a substituent including a heteroatom or a cyclopentadiene having at least two or more lower alkyl groups, lower alkenyl groups, or lower alkynyl groups. Accordingly, electron donating increases by the substituents of the cyclopentadiene, so that the cyclopentadiene may be well bonded to an iridium atom of the organometallic compound. Accordingly, the organometallic compound may have high thermal stability. In addition, the organometallic compound may be liquid at room temperature, and may have relatively high volatility.

The organometallic compound according to some implementations may be used as a raw material suitable for a chemical vapor deposition (CVD) process or an atomic layer deposition (ALD) process.

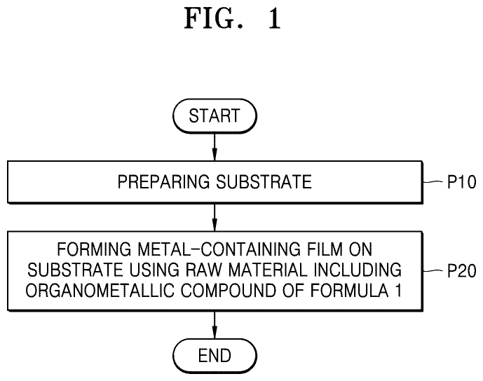

FIG. 1 is a flowchart illustrating a method of manufacturing a semiconductor device according to some implementations.

Referring to FIG. 1, first, a substrate may be provided in operation P10.

The substrate may include a material selected from a semiconductor substrate, a silicon on insulator (SOI) substrate, quartz, glass, plastic, a metal-containing film, an insulating film, and combinations thereof. For example, the semiconductor substrate may include a material selected from, but is not limited to, Si, Ge, SiGe, GaP, GaAs, SiC, SiGeC, InAs, InP, and combinations thereof. The plastic may include a material selected from, but is not limited to, polyimide, polyethylene terephthalate (PET), polyethylene naphthalate (PEN), poly methyl methacrylate (PMMA), polycarbonate (PC), polyether sulfone (PES), polyester, and combinations thereof. The metal-containing film may be made of, but is not limited to, Ti, TiN, Ta, TaN, Co, Ru, Zr, Hf, La, W, or a combination thereof. The substrate may include silicon nitride, titanium nitride, tantalum nitride, silicon oxide, niobium oxide, zirconium oxide, hafnium oxide, lanthanum oxide, or a combination thereof.

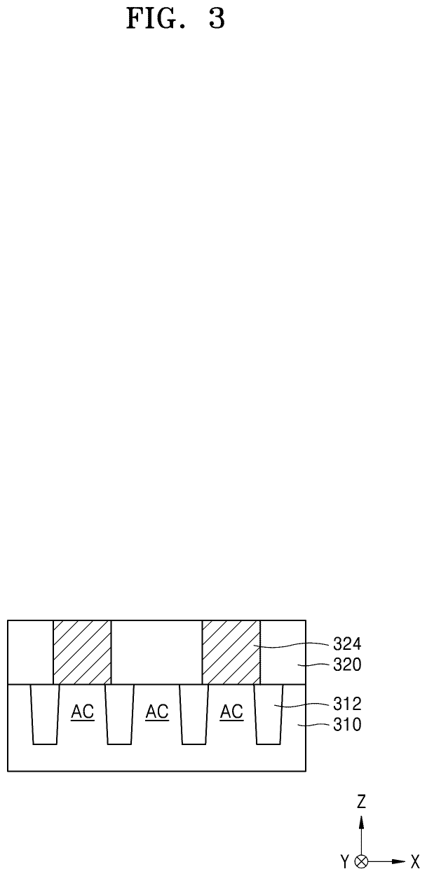

In some implementations, the substrate may have a configuration as described below with respect to a substrate 310 with reference to FIG. 3.

Next, in operation P20, a metal-containing film may be formed on the substrate using a raw material for forming a metal-containing film including the organometallic compound of Formula 1.

The raw material for forming a metal-containing film may include the organometallic compound according to implementations. In some implementations, the raw material for forming a metal-containing film may include at least one organometallic compound among the organometallic compounds represented by Formula 1. In some implementations, the organometallic compound may be liquid at room temperature.

In some implementations, the metal-containing film to be formed may be formed of an iridium-containing film.

In other implementations, the metal-containing film to be formed may further include another metal in addition to iridium. For example, when the metal-containing film to be formed is a film including a metal or a semimetal other than iridium, the raw material for forming a metal-containing film may include a compound including the desired metal or semimetal (hereinafter referred to as “another precursor”) in addition to the organometallic compound according to some implementations.

For example, the another precursor may include lithium (Li), sodium (Na), potassium (K), magnesium (Mg), calcium (Ca), strontium (Sr), barium (Ba), titanium (Ti), zirconium (Zr), hafnium (Hf), chromium (Cr), molybdenum (Mo), tungsten (W), manganese (Mn), iron (Fe), cobalt (Co), rhodium (Rh), niobium (Nb), tantalum (Ta), nickel (Ni), palladium (Pd), platinum (Pt), copper (Cu), silver (Ag), gold (Au), zinc (Zn), aluminum (Al), gallium (Ga), indium (In), germanium (Ge), tin (Sn), lead (Pb), antimony (Sb), bismuth (Bi), yttrium (Y), lanthanum (La), cerium (Ce), praseodymium (Pr), neodymium (Nd), It may include elements such as promethium (Pm), samarium (Sm), europium (Eu), gadolinium (Gd), terbium (Tb), dysprosium (Dy), holmium (Ho), erbium (Er), thulium (Tm), ytterbium (Yb), and lutetium (Lu), but the precursors are not limited to the above-exemplified elements.

In some implementations, the raw material for forming a metal-containing film may further include an organic solvent in addition to the organometallic compound according to implementations.

The kind of the organic solvent is not particularly limited, and organic solvents known in the art may be used. For example, as the organic solvent, acetic esters such as ethyl acetate, butyl acetate, methoxyethyl acetate, etc.; ethers such as tetrahydrofuran, tetrahydropyran, ethylene glycol dimethyl ether, diethylene glycol dimethyl ether, triethylene glycol dimethyl ether, dibutyl ether, etc.; ketones such as methylbutyl ketone, methylisobutyl ketone, ethylbutyl ketone, dipropyl ketone, diisobutyl ketone, methylamyl ketone, cyclohexanone, methyl cyclohexanone, etc.; hydrocarbons such as hexane, cyclohexanone, cyclohexane, dimethylcyclohexane, ethylcyclohexane, heptane, octane, toluene, xylene, etc.; hydrocarbons having a cyano group, such as cyanopropane, 1-cyanobutane, 1-cyanohexane, cyanocyclohexane, cyanobenzene, 1,3-dicyanopropane, 1,4-dicyanobutane, 1,6-dicyanohexane, 1,4-dicyanocyclohexane, 1,4-dicyanobenzene; pyridine; lutidine, etc. may be used. The above-exemplified organic solvents may be used alone or as a mixed solvent of at least two kinds, in consideration of solubility of a solute, temperature of use, boiling point, flash point, etc.

A CVD process or an ALD process may be used to form a metal-containing film according to operation P20 of FIG. 1. A composition for forming a metal-containing film including the organometallic compound according to implementations may be suitably used in a chemical deposition process such as a CVD process or an ALD process.

In some implementations, when the composition for forming a metal-containing film is introduced into a deposition apparatus, the composition for forming a metal-containing film may be introduced into a reaction chamber, in which a substrate is placed, together with a carrier gas such as argon, nitrogen, helium, or the like, which is used as needed, in a vaporized state. In other implementations, when the composition for forming a metal-containing film is introduced into a deposition apparatus, the composition for forming a metal-containing film may be transported to a vaporization chamber in a liquid or solution state, vaporized by heating and/or depressurization in the vaporization chamber to a vapor state, and then introduced into a reaction chamber.

The process of forming a metal-containing film according to the operation P20 of FIG. 1 may include: a process of vaporizing a composition for forming a metal-containing film including an organometallic compound of Formula 1, introducing the vaporized composition into a reaction chamber in which a substrate is placed, and depositing the organometallic compound on the surface of the substrate to form an organometallic precursor thin film on the substrate; and a process of reacting the organometallic precursor thin film with a reactive gas to form a metal-containing film on the surface of the substrate.

The reactive gas may refer to a gas that reacts with the precursor thin film. For example, the reactive gas may be an oxidizing gas, a reducing gas, or a nitriding gas.

The oxidizing gas may be selected from O₂, O₃, O₂ plasma, H₂O, NO₂, NO, N₂O (nitrous oxide), CO, CO₂, H₂O₂, HCOOH, CH₃COOH, (CH₃CO)₂O, alcohols, peroxides, sulfur oxides, and combinations thereof.

The reducing gas may be H₂.

The nitriding gas may be selected from NH₃, N₂ plasma, organic amine compounds such as monoalkyl amines, dialkylamines, trialkylamines, alkylenediamines, hydrazine compounds, and combinations thereof.

When forming a metal oxide film or metal film including iridium in the operation P20 of FIG. 1, the oxidizing gas may be used as the reactive gas. When forming a metal nitride film including iridium in the operation P20 of FIG. 1, the nitriding gas may be used as the reactive gas.

In some implementations, in order to form a metal-containing film in the operation P20 of FIG. 1, a thermal CVD process in which a raw material gas including an organometallic compound according to implementations reacts with a reactive gas only by heat to form a thin film, a plasma CVD process using heat and plasma, a photo CVD process using heat and light, a photo-plasma CVD process using heat, light, and plasma, or an ALD process may be used.

In forming a metal-containing film according to the operation P20 of FIG. 1, deposition conditions may be controlled according to the thickness and type of the desired metal-containing film and the thermal characteristics of the organometallic compound used as a raw material. In some implementations, the deposition conditions may include an input flow rate of the composition for forming a metal-containing film, an input flow rate of a carrier gas, an input flow rate of a reactive gas, pressure, radio frequency (RF) power, reaction temperature (substrate temperature), etc.

In forming a metal-containing film according to the operation P20 of FIG. 1, when an ALD process is used, the film thickness of the metal-containing film may be controlled by controlling the number of cycles of the ALD process. The method of forming a metal-containing film on the substrate using an ALD process may include: a process of vaporizing a raw material gas for forming a metal-containing film including an organometallic compound according to some implementations to form a vapor and introducing the vapor into a deposition reaction unit; a process of forming a precursor thin film on the surface of the substrate using the vapor; a process of exhausting unreacted raw material gas remaining in a reaction space on the substrate; and a process of forming a metal-containing film on the surface of the substrate by chemically reacting the precursor thin film with a reactive gas.

The organometallic compounds according to implementations may have improved thermal stability and may have relatively high volatility. Therefore, a metal-containing film having excellent properties may be formed by using the organometallic compound according to implementations.

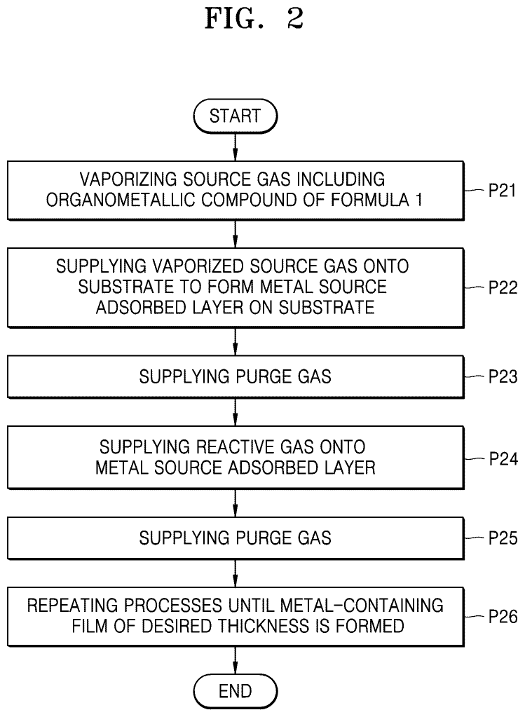

FIG. 2 is a flowchart specifically illustrating a method for forming a metal-containing film according to the method of manufacturing a semiconductor device according to some implementations. Hereinafter, with reference to FIG. 2, a method of forming a metal-containing film using an ALD process according to the operation P20 of FIG. 1 will be described.

Referring to FIG. 2, a source gas including an organometallic compound having a structure of Formula 1 may be vaporized in operation P21.

In some implementations, the source gas may be composed of the above-described raw material for forming a metal-containing film. The process of vaporizing the source gas may be performed at a temperature of about 0° C. to about 200° C. When vaporizing the source gas, the pressure inside a raw material container or vaporization chamber may be about 1 Pa to about 10,000 Pa.

In operation P22 of FIG. 2, the source gas vaporized according to the operation P21 may be supplied onto a substrate to form, on the substrate, a metal source adsorption layer including iridium atoms. In such implementations, a reaction temperature may be selected within a range from room temperature to about 800° C., for example, within a range from about 150° C. to about 900° C. and within a range from about 250° C. to about 800° C. Reaction pressure may be about 1 Pa to about 10,000 Pa, for example, about 10 Pa to about 1,000 Pa.

An adsorption layer including a chemical adsorption layer and physical adsorption layer of the vaporized source gas may be formed on the substrate by supplying the vaporized source gas onto the substrate,

In operation P23 of FIG. 2, a purge gas may be supplied onto the substrate to remove unnecessary byproducts on the substrate.

As the purge gas, an inert gas such as Ar, He, or Ne, or an N₂ gas may be used.

In other implementations, instead of the purge process, a reaction space in which the substrate is placed may be depressurized and exhausted. In such implementations, for the depressurization, the pressure of the reaction space may be maintained at about 0.01 Pa to about 300 Pa, for example, about 0.01 Pa to about 100 Pa.

In some implementations, a process of heating a substrate on which a metal source adsorption layer including iridium atoms is formed or heat-treating a reaction chamber in which the substrate is accommodated may be further performed. The heat treatment may be performed at a temperature of room temperature to about 800° C., for example, about 50° C. to about 800° C.

In operation P24 of FIG. 2, a reactive gas may be supplied onto the metal source adsorption layer formed on the substrate to form a metal-containing film in an atomic layer unit.

In some implementations, when forming a metal oxide film or metal film including iridium atoms on the substrate, the reactive gas may be an oxidizing gas selected from 02, O₃, O₂ plasma, H₂O, NO₂, NO, N₂O (nitrous oxide), CO, CO₂, H₂O₂, HCOOH, CH₃COOH, (CH₃CO)₂O, alcohols, peroxides, sulfur oxides, and combinations thereof.

In some implementations, when forming a metal nitride film including iridium atoms on the substrate, the reactive gas may be a nitriding gas selected from NH₃, N₂ plasma, organic amine compounds such as monoalkyl amines, dialkylamines, trialkylamines, and alkylenediamines, hydrazine compounds, and combinations thereof.

In other implementations, the reactive gas may be a reducing gas, for example, H₂.

During the operation P24 of FIG. 2, the reaction space may be maintained at a temperature of room temperature to about 800° C., for example, a temperature of about 150° C. to about 900° C., or a temperature of about 250° C. to about 800° C., so that the metal source adsorption layer including iridium atoms and the reactive gas can sufficiently react with each other. During the operation P24 of FIG. 2, the pressure of the reaction space may be about 1 Pa to about 10,000 Pa, for example, about 10 Pa to about 1,000 Pa.

During the operation P24 of FIG. 2, the reactive gas may be plasma-treated. The RF output during the plasma treatment may be about 0 W to about 1,500 W, for example, about 50 W to about 600 W.

In operation P25 of FIG. 2, a purge gas may be supplied onto the substrate to remove unnecessary byproducts on the substrate.

As the purge gas, an inert gas such as Ar, He, or Ne, or an N₂ gas may be used.

In operation P26 of FIG. 2, the processes P21 to P25 of FIG. 2 may be repeated until a metal-containing film of a desired thickness is formed.

A thin film deposition process consisting of a series of processes P21 to P25 of FIG. 2 is considered one cycle, and this cycle may be repeated several times until a metal-containing film of a desired thickness is formed. In some implementations, after performing the one cycle, an exhaust process using a purge gas may be performed similarly to the operation P23 or the operation P25 to exhaust unreacted gases from the reaction chamber, and then a subsequent cycle may be performed.

In some implementations, raw material supply conditions (for example, vaporization temperature or vaporization pressure of the raw material), reaction temperature, reaction pressure, and the like may be controlled to control the deposition rate of the metal-containing film. When the deposition rate of the metal-containing film is too high, the characteristics of the obtained metal-containing film may deteriorate, and when the deposition rate of the metal-containing film is too low, the productivity thereof may decrease. For example, the deposition rate of the metal-containing film may be about 0.01 nm/min to about 100 nm/min, for example, about 1 nm/min to about 50 nm/min.

The process of forming a metal-containing film described with reference to FIG. 2 is merely an example, and various modifications and changes are possible within the scope of this disclosure.

For example, in order to form a metal-containing film on the substrate, an organometallic compound having a structure of Formula 1 may be supplied onto the substrate together with at least one of another precursor, a reactive gas, a carrier gas, and a purge gas, or may be supplied sequentially. More detailed configurations of other precursors, reactive gases, carrier gases, and purge gases that can be supplied onto the substrate together with the organometallic compound having a structure of Formula 1 have been described as above.

In other implementations, in the process of forming a metal-containing film described with reference to FIG. 2, reactive gases may be supplied onto the substrate between the processes P21 to P25, respectively.

According to some implementations, when forming a metal-containing film using an ALD process, energy such as plasma, light, or voltage may be applied. The timing at which the energy is applied may be selected in various ways. For example, when a source gas including an organometallic compound according to some implementations is introduced into a reaction chamber, when the source gas is adsorbed onto the substrate, during the exhaust process using the purge gas, when the reactive gas introduced into the reaction chamber, or between these points in time, energy such as plasma, light, or voltage may be applied.

According to some implementations, the process of forming a metal-containing film using the organometallic compound having a structure of Formula 1 may further include an annealing process under an inert atmosphere, an oxidizing atmosphere, or a reducing atmosphere. The annealing process may be performed under temperature conditions selected within a range of about 200° C. to about 1,000° C., for example, about 250° C. to about 500° C., but the annealing temperature is not limited to the above-exemplified temperatures.

According to some implementations, various types of metal-containing films may be formed by appropriately selecting an organometallic compound, other precursors used together with the organometallic compound, a reactive gas, and thin film formation process conditions. In some implementations, the metal-containing film formed according to some implementations may include iridium atoms. For example, the metal-containing film may include an iridium film, an iridium oxide film, an iridium nitride film, an iridium alloy film, and an iridium-containing composite oxide film.

A metal-containing film formed by a method according to some implementations may be used as a material for various components constituting a semiconductor device. For example, the metal-containing film may be used as a constituent material of an insulating film constituting a logic device or a memory device. The logic device may include a central processing unit (CPU), a controller, an application specific integrated circuit (ASIC), etc. The memory device may include a volatile memory device such as dynamic random access memory (DRAM) or static random access memory (SRAM), or a non-volatile memory device such as phase-change random access memory (PRAM), magnetoresistive random access memory (MRAM), ferroelectric random access memory (FeRAM), or resistive random access memory (RRAM). However, the uses of the metal-containing film are not limited to those exemplified above.

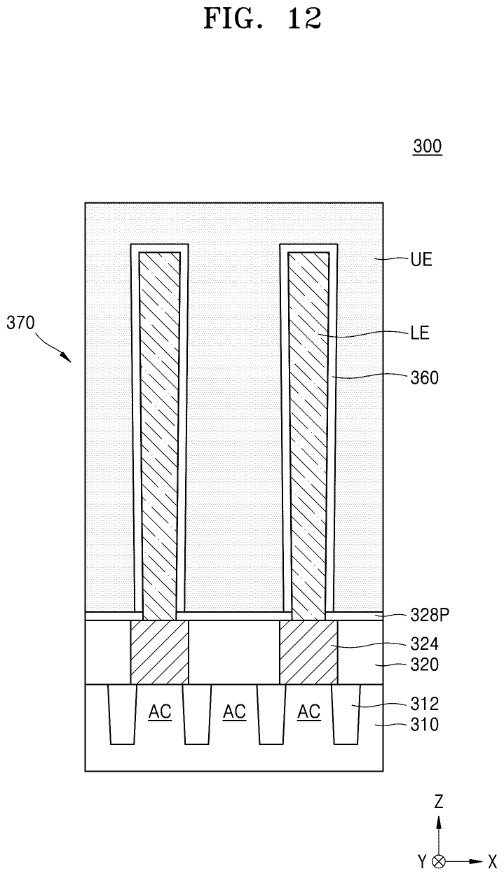

FIGS. 3 to 12 are cross-sectional views illustrating a process sequence for explaining a method of manufacturing a semiconductor device 300 (refer to FIG. 12) according to some implementations.

Referring to FIG. 3, after an interlayer insulating film 320 is formed on a substrate 310 including a plurality of active regions AC, a plurality of conductive regions 324 extending through the interlayer insulating film 320 and connected to the plurality of active regions AC may be formed.

The substrate 310 may include a semiconductor such as Si or Ge, or a compound semiconductor such as SiGe, SiC, GaAs, InAs, or InP. The substrate 310 may include conductive regions, such as wells doped with impurities or structures doped with impurities. The plurality of active regions AC may be defined by a plurality of element isolation regions 312 formed on the substrate 310. The element isolation region 312 may be made of a silicon oxide film, a silicon nitride film, a silicon oxynitride film, or a combination thereof. The interlayer insulating film 320 may include a silicon oxide film. The plurality of conductive regions 324 may be connected to one terminal of a switching element such as a field effect transistor formed on the substrate 310. The plurality of conductive regions 324 may be made of polysilicon, metal, conductive metal nitride, metal silicide, or a combination thereof.

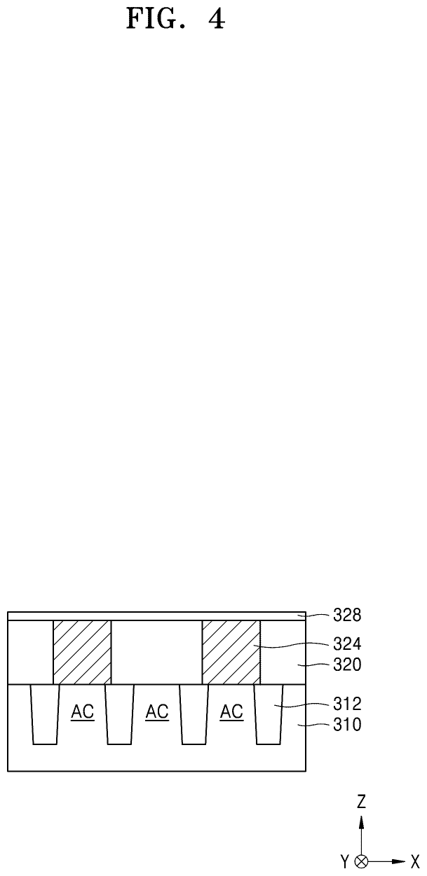

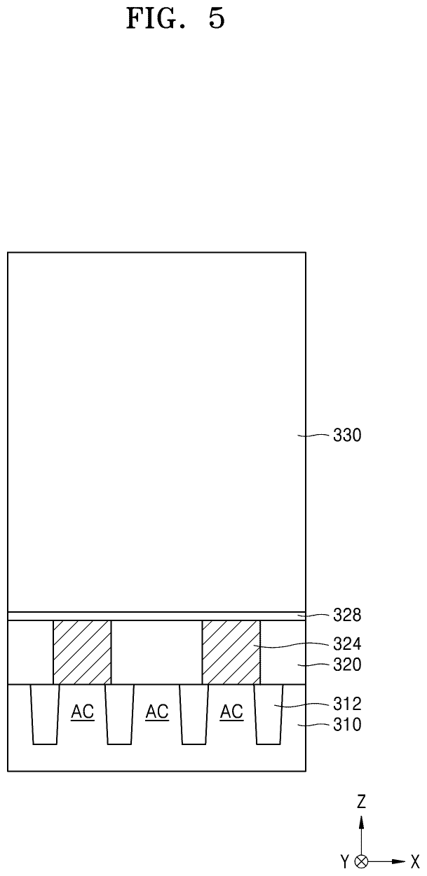

Referring to FIG. 4, an insulating layer 328 covering the interlayer insulating film 320 and the plurality of conductive regions 324 may be formed. The insulating layer 328 may be used as an etch stop layer. The insulating layer 328 may be made of an insulating material having an etch selectivity with respect to the interlayer insulating film 320 and a mold film 330 formed in a subsequent process (refer to FIG. 5). The insulating layer 328 may be made of silicon nitride, silicon oxynitride, or a combination thereof.

Referring to FIG. 5, a mold film 330 may be formed on the insulating layer 328.

The mold film 330 may be formed of an oxide film. For example, the mold film 330 may include an oxide film such as borophosphosilicate glass (BPSG), phosphosilicate glass (PSG), or undoped silicate glass (USG). To form the mold film 330, a thermal CVD process or a plasma CVD process may be used. The mold film 330 may be formed to a thickness of about 1000 Å to about 20000 Å, but the thickness thereof is not limited thereto. In some implementations, the mold film 330 may include a support film. The support film may be formed of a material having an etch selectivity with respect to the mold film 330. The support film may be made of a material having a relatively low etch rate with respect to an etching atmosphere used when removing the mold film 330 in a subsequent process, for example, an etchant including ammonium fluoride (NH₄F), hydrofluoric acid (HF), and water. In some implementations, the support film may be made of silicon nitride, silicon carbon nitride, tantalum oxide, titanium oxide, or a combination thereof.

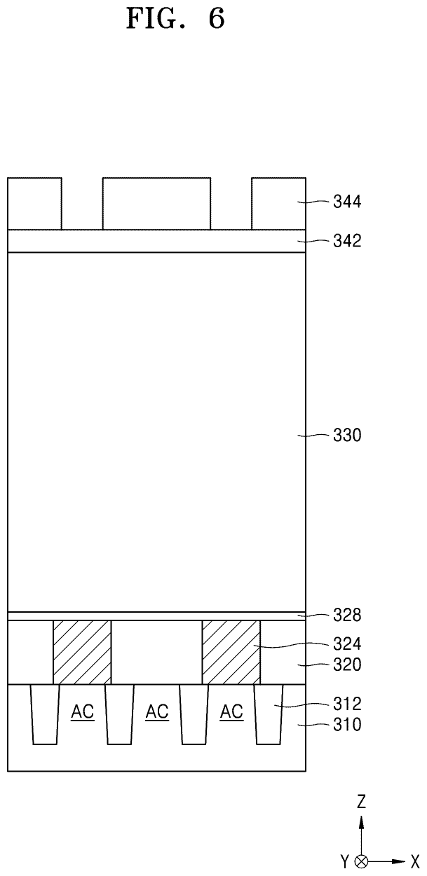

Referring to FIG. 6, a sacrificial film 342 and a mask pattern 344 may be formed sequentially on the mold film 330.

The sacrificial film 342 may be formed of an oxide film. The mask pattern 344 may be formed of an oxide film, a nitride film, a polysilicon film, a photoresist film, or a combination thereof. A region where a lower electrode of a capacitor is to be formed may be defined by the mask pattern 344.

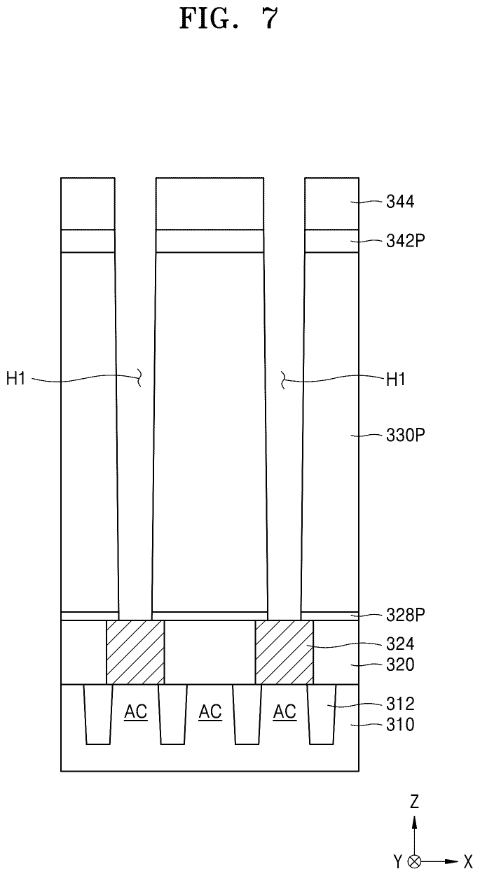

Referring to FIG. 7, a sacrificial pattern 342P and a mold pattern 330P that define a plurality of holes H1 may be formed by dry etching the sacrificial film 342 and the mold film 330 using the mask pattern 344 as an etching mask and using the insulating layer 328 as an etch stop layer. In such implementations, the insulating layer 328 may also be etched by over-etching to form an insulating pattern 328P that exposes the plurality of conductive regions 324.

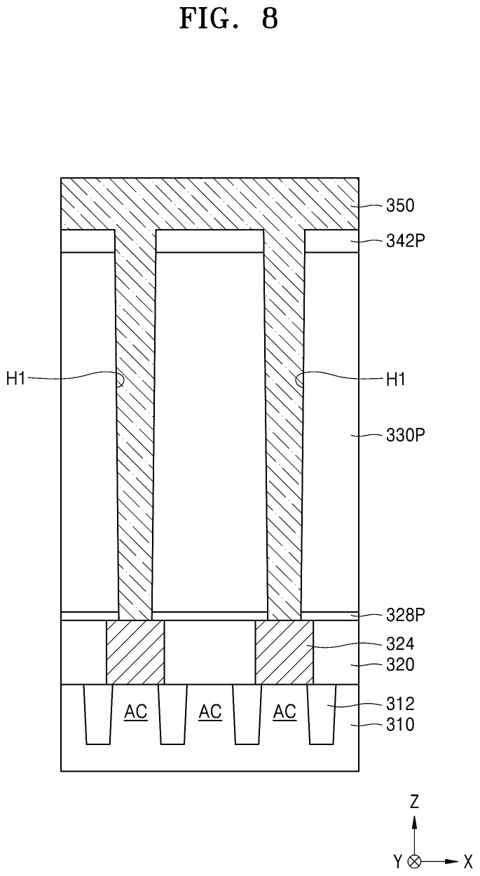

Referring to FIG. 8, after removing the mask pattern 344 from the resultant of FIG. 7, a conductive film 350 for forming a lower electrode, the conductive film 350 covering the exposed surface of the sacrificial pattern 342P while filling the plurality of holes H1, may be formed.

To form the conductive film 350 for forming a lower electrode, a CVD process, a metal organic CVD (MOCVD) process, or an ALD process may be used. When the conductive film 350 for forming a lower electrode is formed using an ALD process, a metal-containing film may be formed by the operation P20 of FIG. 1 or the method described with reference to FIG. 2 to form at least a portion of the conductive film 350 for forming a lower electrode.

In some implementations, the operation P20 of FIG. 1 or the processes described with reference to FIG. 2 may be performed to form the conductive film 350 for forming a lower electrode. In forming the conductive film 350 for forming a lower electrode, an organometallic compound having a structure of Formula 1 may be used. Since the organometallic compound has high thermal stability, a high-quality conductive film 350 for forming a lower electrode can be formed, and since the organometallic compound has high volatility, the mass productivity of the conductive film 350 for forming a lower electrode can be improved.

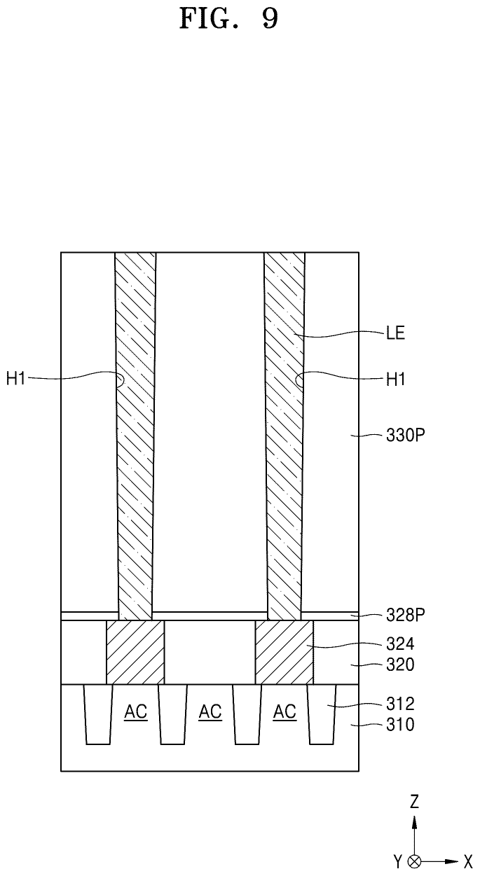

Referring to FIG. 9, a plurality of lower electrodes LE may be formed from the conductive film 350 for forming a lower electrode by partially removing the upper portion of the conductive film 350.

In order to form the plurality of lower electrodes LE, an etchback process or a chemical mechanical polishing (CMP) process may be used to remove a portion of the upper side of the conductive film 350 for forming a lower electrode and the sacrificial pattern 342P (refer to FIG. 8) until the upper surface of the mold pattern 330P is exposed.

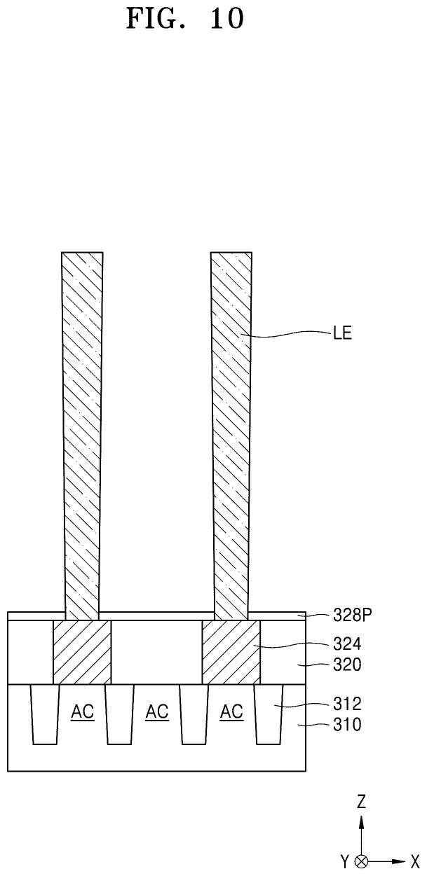

Referring to FIG. 10, the mold pattern 330P may be removed from the resultant of FIG. 9 to expose the outer surfaces of the plurality of lower electrodes LE. In some implementations, the mold pattern 330P may be removed by a lift-off process. The mold pattern 330P may be removed using an etchant including ammonium fluoride (NH₄F), hydrofluoric acid (HF), and water.

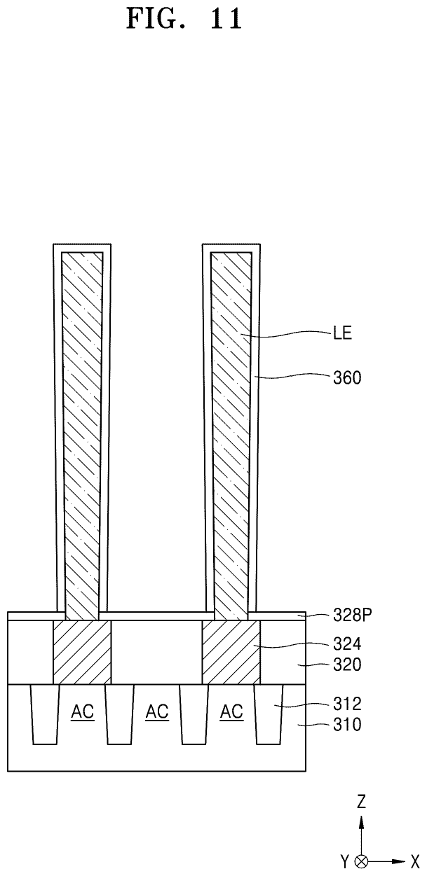

Referring to FIG. 11, a dielectric film 360 may be formed on the plurality of lower electrodes LE.

The dielectric film 360 may be formed to conformally cover the exposed surfaces of the plurality of lower electrodes LE.

The dielectric film 360 may be formed by an ALD process. In some implementations, the dielectric film 360 may include a metal oxide having a high dielectric constant. The dielectric film 360 may include, but is not limited to, zirconium oxide, hafnium oxide, titanium oxide, tantalum oxide, lanthanum oxide, aluminum oxide, yttrium oxide, strontium titanium oxide, niobium oxide, barium strontium titanium oxide, or a combination thereof.

Prior to the formation of the dielectric film 360, a first interface interposed between the plurality of lower electrodes LE and the dielectric film 360 may be formed. The first interface may be formed using an organometallic compound having a structure of Formula 1.

Referring to FIG. 12, an upper electrode UE may be formed on the dielectric film 360 from the resultant of FIG. 11. The lower electrodes LE, the dielectric film 360, and the upper electrode UE may form a capacitor 370.

The upper electrode UE may be formed to be in contact with the surface of the dielectric film 360 and the upper surface of the insulating pattern 328P. In order to form the upper electrode UE, a CVD process, a metal organic CVD (MOCVD) process, or an ALD process may be used. When the upper electrode UE is formed using an ALD process, a metal-containing film may be formed by the operation P20 of FIG. 1 or the method described with reference to FIG. 2 to form at least a portion of the upper electrode UE.

In some implementations, the operation P20 of FIG. 1 or the processes described with reference to FIG. 2 may be performed to form the upper electrode UE. In forming the upper electrode UE, an organometallic compound having a structure of Formula 1 may be used. Since the organometallic compound has high thermal stability, a high-quality upper electrode UE can be formed, and since the organometallic compound has high volatility, the mass productivity of the upper electrode UE can be improved.

Prior to the formation of the upper electrode UE, a second interface may be formed between the upper electrode UE and the dielectric film 360. The second interface may be formed using an organometallic compound having a structure of Formula 1.

In the method of manufacturing a semiconductor device described with reference to FIGS. 3 to 12, a case where a plurality of lower electrodes LE have a pillar shape is described as an example, but the shape of the lower electrodes is not limited thereto. For example, each of the plurality of lower electrodes LE may have a cross-sectional structure of a cup shape or a cylinder shape with a closed bottom.

In the method of manufacturing a semiconductor device according to some implementations described with reference to FIGS. 3 to 12, the lower electrodes LE and upper electrode UE having excellent quality and improved mass productivity can be formed by using an organometallic compound having a structure of Formula 1.

Hereinafter, specific examples and comparative examples of organometallic compounds according to some implementations will be described. However, the organometallic compounds are not limited to the following examples.

### Synthesis Example 1

### Synthesis of (trimethylsilylcyclopentadiene) (1,3-cyclohexadiene)iridium

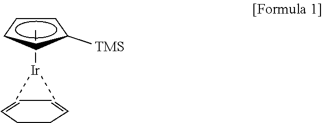

### (1) Synthesis of chlorobis(1,3-cyclohexadiene)iridium compound

298.6 mg (1.0 mmol, 1.0 equiv) of IrCl3·nH₂O was put into a stopcock round-bottom flask equipped with a stirring bar, and the inside of the flask was replaced with an inert gas through a Schlenk line. Next, 6 mL of ethanol (EtOH), 4 mL of water, and 953 μL (10 mmol, 10 equiv) of 1,3-cyclohexadiene were added to the flask and stirred for about 12 hours. Next, an off-white solid produced by a reaction due to the stirring was filtered through a glass frit filter, and then the filtered solid was washed using a small amount of isopropanol. Next, volatile substances remaining in vacuum were removed to obtain a chlorobis(1,3-cyclohexadiene)iridium compound (160 mg, 0.412 mmol, yield: 41%).

### (2) Synthesis of (trimethylsilylcyclopentadiene) (1,3-cyclohexadiene)iridium

In order to prepare a lithium trimethylsilyl cyclopentadiene solution, trimethylsilyl cyclopentadiene (0.6 mmol) and tetrahydrofuran (2 mL, 0.3 M) were put into a stopcock round-bottom flask equipped with a stirring bar under inert conditions. Thereafter, the flask was cooled to −78° C., and then an nBuLi solution (1.6 M in hexane, 375 μL, 0.6 mmol, 1.0 equiv) was slowly added to prepare a lithium trimethylsilyl cyclopentadiene solution.

Next, the chlorobis(1,3-cyclohexadiene)iridium compound (38.8 mg, 0.1 mmol, 1.0 equiv) obtained through the above-described process and tetrahydrofuran (1 mL, 0.1 M) were put into another stopcock round-bottom flask equipped with a stirring bar under inert conditions. Next, these materials were cooled to −78° C., and the prepared lithium trimethylsilyl cyclopentadiene (0.11 mmol, 1.1 equiv) was slowly added and stirred at the same temperature for 2 hours. Next, the temperature was slowly increased to room temperature, a reaction was carried out for 12 hours, and then stirring was carried out at 70° C. for 2 hours.

Next, pentane (4 mL) was added to the solution resulting from the reaction to generate a salt, the salt was removed from the solution through a glass frit filter to obtain a filtrate, and the obtained filtrate was evaporated in vacuum to obtain a product. The product was provided into a round-bottom flask, and the inside of the round-bottom flask was replaced with an inert gas using a Schlenk line. Next, sublimation purification was performed by heating under high vacuum conditions to obtain a (trimethylsilylcyclopentadiene) (1,3-cyclohexadiene)iridium compound in high purity (yield: 34%).

### (Analysis Value)

### (1) ¹H NMR (500 MHz, C6D6):

δ 5.08-5.03 (m, 2H), 4.98-4.95 (m, 2H), 4.90-4.86 (m, 2H), 3.56-3.52 (m, 2H), 1.67-1.58 (m, 2H), 1.48-1.39 (m, 2H), 0.19 (s, 9H)

### (2) High Resolution TGA

Mass 50% reduction temperature (TG 50%): 224° C. (N₂, heating rate: 5° C./min, measurement temperature: 30° C. to 500° C., isothermal temperature: 30° C.)

### (3) Modulated Differential Scanning Calorimeter

### Thermal decomposition initiation temperature (DSCo): 337° C. (Ar, heating rate: 10° C./min, measurement temperature: 400° C., isothermal temperature: 40° C.)

### Synthesis Example 2

### Synthesis of (trimethylsilylcyclopentadiene) (2,3-dimethyl-1,3-butadiene)iridium

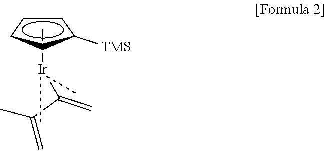

[Ir(COE)2Cl]2 (200 mg, 0.22 mmol, 1.0 equiv) was put into a stopcock round-bottom flask equipped with a stirring bar, and the inside of the flask was replaced with an inert gas through a Schlenk line. Next, 2,3-dimethyl-1,3-butadiene (2 mL) was added to the flask and stirred at room temperature for about 1 hour. Next, an off-white solid produced by a reaction due to the stirring was filtered through a glass frit filter, and then the filtered solid was washed using a small amount of isopropanol. Next, volatile substances remaining in vacuum were removed to obtain a chlorobis(2,3-dimethyl-1,3-butadiene)iridium compound (yield: 72%).

Next, a lithium trimethylsilyl cyclopentadiene solution was prepared in the same manner as in Synthesis Example 1 as described above, and (trimethylsilylcyclopentadiene) (2,3-dimethyl-1,3-butadiene)iridium was obtained with high purity using the lithium trimethylsilyl cyclopentadiene solution and chlorobis(2,3-dimethyl-1,3-butadiene)iridium compound in the same manner as in Synthesis Example 1 as described above (yield 34%).

### (Analysis Value)

(1) ¹H NMR (500 MHz, CDCl3):

δ 5.14 (t, J=1.5 Hz, 2H), 5.06 (t, J=1.5 Hz, 2H), 2.53 (d, J=1.8 Hz, 2H), 2.21 (s, 6H), 0.20 (s, 9H), −0.05 (d, J=1.8 Hz, 2H)

### (2) High Resolution TGA

Mass 50% reduction temperature (TG 50%): 207° C. (N₂, heating rate: 5° C./min, measurement temperature: 30° C. to 500° C., isothermal temperature: 30° C.)

### (3) Modulated Differential Scanning Calorimeter

Thermal decomposition initiation temperature (DSCo): 364° C. (Ar, heating rate: 10° C./min, measurement temperature: 400° C., isothermal temperature: 40° C.)

### Synthesis Example 3

### Synthesis of (2-methoxyethylcyclopentadiene) (2,3-dimethyl-1,3-butadiene)iridium

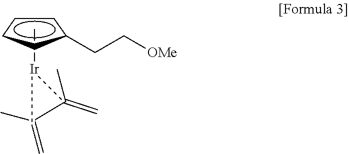

The inside of a stopcock round-bottom flask equipped with a stirring bar was replaced with an inert gas through a Schlenk line, and then sodium hydride (96 mg, 4 mmol, 1 equiv) and anhydrous tetrahydrofuran (2 mL) were put into the flask and stirred in a bath at 0° C. Next, in order to prevent a pressure increase due to hydrogen gas generated by the stirring, an Ar balloon was connected to the flask, and cracked cyclopentadiene (330.5 μL, 4 mmol, 1 equiv) was slowly added to the flask and maintained at 0° C. for 1 hour. Next, 2-methoxyethyltosylate (607.5 μL, 3.35 mmol, 1 equiv) diluted with 5 mL of anhydrous tetrahydrofuran was slowly added to 1.75 mL of a sodium cyclopentadiene solution at 0° C. and stirred at room temperature for 12 hours. When the solution turned dark purple, tetrahydrofuran was added to completely react the solution. Next, cold distilled water was added to the reaction product to remove a salt, an organic solvent layer was separated by ether, and the remaining water was completely removed using magnesium sulfate. Next, the solvent from which water was removed was evaporated in a rotary evaporator, heated under high vacuum conditions, and fractional distillation at 60° C. was performed to obtain 2-methoxyethylcyclopentadiene (yield 61%).

Next, a chlorobis(2,3-dimethyl-1,3-butadiene)iridium compound was prepared in the same manner as in Synthetic Example 2 as described above, and the chlorobis(2,3-dimethyl-1,3-butadiene)iridium compound and tetrahydrofuran (1 mL, 0.1 M) were put into another stopcock round-bottom flask equipped with a stirring bar under inert conditions. Next, the resulting materials were cooled to −78° C., and the 2-methoxyethylcyclopentadiene was slowly added thereto, and stirred at the same temperature for 2 hours. Next, the temperature was slowly increased to room temperature, a reaction was carried out for 12 hours, and then stirring was carried out at 70° C. for 2 hours.

Next, pentane (4 mL) was added to a solution resulting from the reaction to generate a salt, the salt was removed from the solution through a glass frit filter to obtain a filtrate, and the obtained filtrate was evaporated in vacuum to obtain a product. The product was put into a round bottom flask, and the inside of the round bottom flask was replaced with an inert gas using a Schlenk line. Next, (2-methoxyethylcyclopentadiene) (2,3-dimethyl-1,3-butadiene)iridium was obtained with high purity by sublimation purification through heating under high vacuum conditions (yield 34%).

### (Analysis Value)

(1) ¹H NMR (500 MHz, C6D6):

δ 4.92-4.82 (m, 1H), 3.32 (t, J=6.7 Hz, 1H), 3.08 (d, J=3.6 Hz, 1H), 2.61 (d, J=2.0 Hz, 1H), 2.43 (t, J=6.7 Hz, 1H), 2.11 (d, J=3.5 Hz, 2H), 0.36-0.29 (m, 1H)

### (2) High Resolution TGA

Mass 50% reduction temperature (TG 50%): 229° C. (N₂, heating rate: 5° C./min, measurement temperature: 30° C. to 500° C., isothermal temperature: 30° C.)

### (3) Modulated Differential Scanning Calorimeter

Thermal decomposition initiation temperature (DSCo): 261° C. (Ar, heating rate: 10° C./min, measurement temperature: 400° C., isothermal temperature: 40° C.)

### Synthesis Example 4

### Synthesis of (trifluoromethylcyclopentadiene) (2,3-dimethyl-1,3-butadiene)iridium

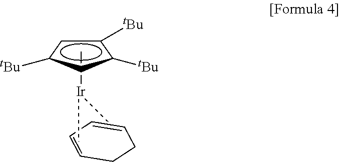

### (1) Synthesis of sodium (tri-tert-butylcyclopentadienide)

Tri-tert-butylcyclopentadiene (410 μL, 1.5 mmol, 1 equiv) and sodium amide (66.3 mg, 1.7 mmol, 1.1 equiv) were put into a Schlenk tube equipped with a stirring bar, and the inside of the tube was replaced with an inert gas through a Schlenk line. Next, tetrahydrofuran (2 mL) was added, and a reaction was performed at 70° C. for 14 hours. During this time, the reaction solution changed from pale yellow to brown. Next, the reaction solution was cooled and passed through a celite filter under an inert gas to remove the generated salt, and the solution was evaporated at low pressure to obtain a solid. Next, the obtained solid was washed with pentane on a filter, washed once more with diethyl ether, and then thoroughly dried to obtain desired sodium (tri-tert-butylcyclopentadienide).

### (2) Synthesis of (trimethylcyclopentadiene) (2,3-dimethyl-1,3-butadiene)iridium

After a chlorobis(2,3-dimethyl-1,3-butadiene)iridium compound was prepared in the same manner as in Synthetic Example 2 described above, the chlorobis(2,3-dimethyl-1,3-butadiene)iridium compound (196 mg, 0.5 mmol, 1.0 equiv) was put into a stopcock round-bottom flask equipped with a stirring bar under inert conditions, and then tetrahydrofuran (10 mL, 0.05 M) was added thereto. Next, sodium tri-tert-butylcyclopentadienide (141.3 mg, 0.55 mmol, 1.1 equiv) prepared through the above-described process under inert conditions was dissolved in tetrahydrofuran (1 mL, 0.55 M) to prepare a sodium cyclopentadienide solution, and the materials were cooled to −78° C. Then, the sodium cyclopentadienide solution (0.55 mmol, 1.1 equiv) was slowly added, and then the temperature was slowly increased to room temperature. Next, after the temperature was increased to room temperature, a reaction was conducted at 70° C. for 12 hours. After the reaction, the resulting solution was evaporated under vacuum at room temperature, the remaining mixture was washed with pentane, and impurities were removed through a glass frit filter to obtain a filtrate. Next, the filtrate was evaporated in vacuum to obtain a reaction product, and the reaction product was then filtered with neutral aluminum oxide under inert conditions to further remove impurities, thereby obtaining a (trifluorobutylcyclopentadiene) (2,3-dimethyl-1,3-butadiene)iridium compound (yield 39%).

### (Analysis Value)

(1) ¹H NMR (500 MHz, C6D6):

δ 5.02 (s, 2H), 2.62 (d, J=1.7 Hz, 2H), 2.16 (s, 6H), 1.40 (s, 18H), 1.17 (s, 9H), 0.22-0.21 (d, J=1.7 Hz, 2H)

### (2) High Resolution TGA

Mass 50% reduction temperature (TG 50%): 267° C. (N₂, heating rate: 5° C./min, measurement temperature: 30° C. to 500° C., isothermal temperature: 30° C.)

### (3) Modulated Differential Scanning Calorimeter

Thermal decomposition initiation temperature (DSCo): 422° C. (Ar, heating rate: 10° C./min, measurement temperature: 400° C., isothermal temperature: 40° C.)

### Synthesis Examples 1 to 4 and Comparative Example 1

### Evaluation of Characteristics of Compounds

The high resolution TGA mass 50% reduction temperature, TG Residue, and thermal decomposition initiation temperature (DSCo) of the compounds of Formulas 1 to 4 obtained in Examples 1 to 4 and the compound of Formula 5 of Comparative Example 1 described below were evaluated and are shown in Table 1.

### Comparative Example 1

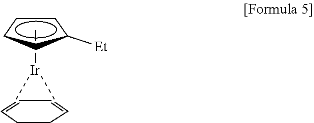

TABLE 1

| | Comparative | | | | |
|---|---|---|---|---|---|
| | Example 1 | Example 1 | Example 2 | Example 3 | Example 4 |
| Formula | 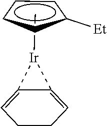 | 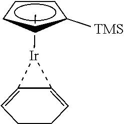 | 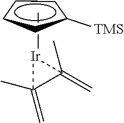 | 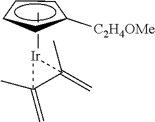 | 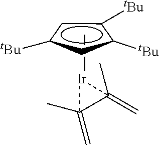 |
| TG50% | 268° C. | 224° C. | 207°C. | 229° C. | 267° C. |
| TG residue | 2.7% | −0% | −0% | 5% | −0% |
| DSCo | 272° C. | 337° C. | 364°C. | 261 C. | 422° C. |
| Phase | oil | oil | oil | oil | oil |

### (1) High Resolution TGA Mass 50% Reduction Temperature

Temperatures at which the weight of each of the compounds of Formula 1 to 4 obtained in Examples 1 to 4 and the compound of Formula 5 obtained in Comparative Example 1 decreased by 50 wt % were measured using a high-resolution TGA under conditions of N₂ gas, a heating rate of 5° C./min, a temperature range of 30° C. to 500° C., and an isothermal temperature of 30° C., and the results thereof are shown in Table 1. The lower the TGA mass 50% reduction temperature, the higher the volatility, which can be determined to be advantageous in terms of mass production.

### (2) TG Residue

TG residues of the compounds of Formulas 1 to 4 obtained in Examples 1 to 4 and the compound of Formula 5 obtained in Comparative Example 1 were measured using a high-resolution TGA under conditions of N₂ gas, a heating rate of 5° C./min, a temperature range of 30° C. to 500° C., and an isothermal temperature of 30° C., and the results thereof are shown in Table 1. The smaller the TG residue, the higher the thermal stability, which makes it difficult for thermal decomposition to occur, and thus it can be determined that each of the compounds is suitable as a raw material for forming a thin film.

### (3) Thermal Decomposition Initiation Temperature

Thermal decomposition initiation temperatures of the compounds of Formulas 1 to 4 obtained in Examples 1 to 4 and the compound of Formula 5 obtained in Comparative Example 1 were measured using differential scanning calorimetry (DSC), and the results are shown in Table 1. The compounds with high thermal decomposition initiation temperature have high thermal stability, so it is difficult for thermal decomposition to occur, and thus it can be determined that each of the compounds is suitable as a raw material for forming a thin film.

From the results in Table 1, it can be found that the compounds of Formula 1, Formula 2, and Formula 3 obtained in Examples 1, 2, and 3 have lower TGA mass 50% reduction temperatures than the compound of Formula 5 obtained in Comparative Example 1. That is, it can be found that the compounds of Formula 1, Formula 2, and Formula 3 obtained in Examples 1, 2, and 3 have higher volatility than the compound of Formula 5 obtained in Comparative Example 1.

From the results in Table 1, it can be found that the compounds of Formula 1, Formula 2, and Formula 3 obtained in Examples 1, 2, and 3 have relatively low TG residue values and relatively high thermal decomposition initiation temperatures compared to the compound of Formula 5 obtained in Comparative Example 1. In addition, it can be found that the compound of Formula 3 obtained in Example 3 has a similar TG Residue value and a similar thermal decomposition initiation temperature compared to the compound of Formula 5 obtained in Comparative Example 1.

That is, it can be found that the compounds of Formula 1 and Formula 2 obtained in Examples 1 and 2 have a relatively low TGA mass 50% reduction temperatures, relatively low TG Residue values, and relatively high thermal decomposition initiation temperatures compared to the compound of Formula 5 obtained from Comparative Example 1.

It can be found that the compound of Formula 3 obtained in Example 3 has a similar TG Residue value, a similar thermal decomposition initiation temperature, and a relatively low TGA mass 50% reduction temperature compared to the compound of Formula 5 obtained in Comparative Example 1.

It can be found that the compound of Formula 4 obtained in Example 4 has a similar TGA mass 50% reduction temperature, a relatively low TG Residue value, and a relatively high thermal decomposition initiation temperature compared to the compound of Formula 5 obtained from Comparative Example 1.

As described above, implementations have been disclosed in the drawings and specification. Although specific terms have been used to describe implementations in this specification, they have been used only for the purpose of explaining the present disclosure and are not intended to limit the meaning or the scope of the present disclosure set forth in the claims. Therefore, a person having ordinary skill in the art will understand that various modifications and equivalent other implementations are possible therefrom. Therefore, the true technical protection scope of the present disclosure should be determined by the technical idea of the appended claims.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While the organometallic compound and methods associated therewith been particularly shown and described with reference to implementations thereof, it will be understood that various changes in form and details may be made therein without departing from the spirit and scope of the following claims.

What is claimed is:

1. An organometallic compound represented by Formula 1 below: 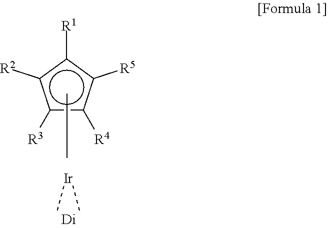
wherein, in Formula 1, R¹, R², R³, R⁴, and R⁵ are each independently a substituent including a heteroatom, hydrogen, an alkyl group having 1 to 10 carbon atoms, an alkenyl group having 2 to 10 carbon atoms, or an alkynyl group having 2 to 10 carbon atoms, and Di is a diene-based hydrocarbon, provided that a case where R¹, R², R³, R⁴, and R⁵ are all hydrogen or methyl groups is excluded or a case where one of R¹, R², R³, R⁴, and R⁵ is an alkyl group and the remaining ones are hydrogen is excluded.

2. The organometallic compound of claim 1,
wherein the heteroatom is Si, O, N, P, or S.

3. The organometallic compound of claim 1,
wherein, in Formula 1, one of R¹, R², R³, R⁴, and R⁵ is a substituent including a heteroatom, and the remaining ones are each independently hydrogen, an alkyl group having 1 to 10 carbon atoms, an alkenyl group having 2 to 10 carbon atoms, or an alkynyl group having 2 to 10 carbon atoms.

4. The organometallic compound of claim 1,
wherein, in Formula 1, at least two of R¹, R², R³, R⁴, and R⁵ are an alkyl group having 1 to 10 carbon atoms, an alkenyl group having 2 to 10 carbon atoms, or an alkynyl group having 2 to 10 carbon atoms, and the remaining ones are hydrogen.

5. The organometallic compound of claim 1,
wherein, in Formula 1, at least two of R¹, R², R³, R⁴, and R⁵ are substituents including a heteroatom, and the remaining ones are each independently hydrogen, an alkyl group having 1 to 10 carbon atoms, an alkenyl group having 2 to 10 carbon atoms, or an alkynyl group having 2 to 10 carbon atoms.

6. The organometallic compound of claim 1,
wherein the organometallic compound of Formula 1 is liquid at room temperature.

7. The organometallic compound of claim 1,
wherein the organometallic compound is represented by Formula 2 below: 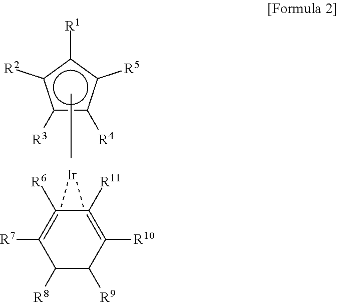
wherein, in Formula 2, R¹, R², R³, R⁴, and R⁵ are each independently a substituent including a heteroatom, hydrogen, an alkyl group having 1 to 10 carbon atoms, an alkenyl group having 2 to 10 carbon atoms, or an alkynyl group having 2 to 10 carbon atoms, provided that a case where R¹, R², R³, R⁴, and R⁵ are all hydrogen or methyl groups is excluded or a case where one of R¹, R², R³, R⁴, and R⁵ is an alkyl group and the remaining ones are hydrogen is excluded, and R⁶, R⁷, R⁸, R⁹, R¹⁰, and R¹¹ are each independently hydrogen, an alkyl group having 1 to 10 carbon atoms, an acyl group having 1 to 10 carbon atoms, or an alkoxy group having 1 to 10 carbon atoms.

8. The organometallic compound of claim 7,
wherein, in Formula 2, one of R¹, R², R³, R⁴, and R⁵ is a substituent including Si as a heteroatom, and the remaining ones are each independently hydrogen.

9. The organometallic compound of claim 1,
wherein the organometallic compound is represented by Formula 3 below: 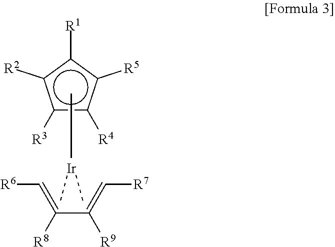
wherein, in Formula 3, R¹, R², R³, R⁴, and R⁵ are each independently a substituent including a heteroatom, hydrogen, an alkyl group having 1 to 10 carbon atoms, an alkenyl group having 2 to 10 carbon atoms, or an alkynyl group having 2 to 10 carbon atoms, provided that a case where R¹, R², R³, R⁴, and R⁵ are all hydrogen or methyl groups is excluded or a case where one of R¹, R², R³, R⁴, and R⁵ is an alkyl group and the remaining ones are hydrogen is excluded, and R⁶, R⁷, R⁸, and R⁹ are each independently hydrogen, an alkyl group having 1 to 10 carbon atoms, an acyl group having 1 to 10 carbon atoms, or an alkoxy group having 1 to 10 carbon atoms.

10. The organometallic compound of claim 9,
wherein, in Formula 3, one of R¹, R², R³, R⁴, and R⁵ is a substituent including Si or O as a heteroatom, and the remaining ones are each independently hydrogen.

11. The organometallic compound of claim 9,
wherein, in Formula 3, at least two of R¹, R², R³, R⁴, and R⁵ are alkyl groups having 1 to 10 carbon atoms, and the remaining ones are hydrogen.

12. A method of manufacturing a semiconductor device, the method comprising forming a metal-containing film on a substrate using an organometallic compound represented by Formula 1 below: 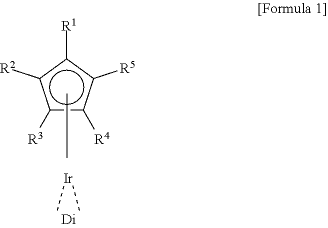
wherein, in Formula 1, R¹, R², R³, R⁴, and R⁵ are each independently a substituent including a heteroatom, hydrogen, an alkyl group having 1 to 10 carbon atoms, an alkenyl group having 2 to 10 carbon atoms, or an alkynyl group having 2 to 10 carbon atoms, and Di is a diene-based hydrocarbon, provided that a case where R¹, R², R³, R⁴, and R⁵ are all hydrogen or methyl groups is excluded or a case where one of R¹, R², R³, R⁴, and R⁵ is an alkyl group and the remaining ones are hydrogen is excluded.

13. The method of claim 12,
wherein the organometallic compound is liquid at room temperature.

14. The method of claim 12,
wherein forming the metal-containing film comprises:
supplying the organometallic compound onto the substrate; and
supplying a reactive gas onto the substrate.

15. The method of claim 12,
wherein the organometallic compound is represented by Formula 2 below: 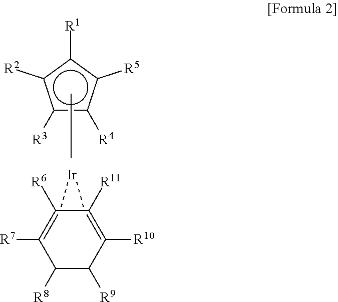
wherein, in Formula 2, R¹, R², R³, R⁴, and R⁵ are each independently a substituent including a heteroatom, hydrogen, an alkyl group having 1 to 10 carbon atoms, an alkenyl group having 2 to 10 carbon atoms, or an alkynyl group having 2 to 10 carbon atoms, provided that a case where R¹, R², R³, R⁴, and R⁵ are all hydrogen or methyl groups is excluded or a case where one of R¹, R², R³, R⁴, and R⁵ is an alkyl group and the remaining ones are hydrogen is excluded, and R⁶, R⁷, R⁸, R⁹, R¹⁰, and R¹¹ are each independently hydrogen, an alkyl group having 1 to 10 carbon atoms, an acyl group having 1 to 10 carbon atoms, or an alkoxy group having 1 to 10 carbon atoms.

16. The method of claim 12,
wherein the organometallic compound is represented by Formula 3 below: 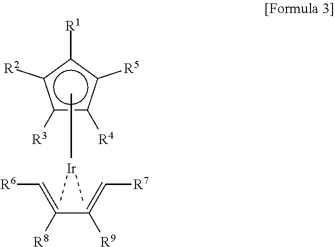
wherein, in Formula 3, R¹, R², R³, R⁴, and R⁵ are each independently a substituent including a heteroatom, hydrogen, an alkyl group having 1 to 10 carbon atoms, an alkenyl group having 2 to 10 carbon atoms, or an alkynyl group having 2 to 10 carbon atoms, provided that a case where R¹, R², R³, R⁴, and R⁵ are all hydrogen or methyl groups is excluded or a case where one of R¹, R², R³, R⁴, and R⁵ is an alkyl group and the remaining ones are hydrogen is excluded, and R⁶, R⁷, R⁸, and R⁹ are each independently hydrogen, an alkyl group having 1 to 10 carbon atoms, an acyl group having 1 to 10 carbon atoms, or an alkoxy group having 1 to 10 carbon atoms.

17. A method of manufacturing a semiconductor device, the method comprising:
forming an insulating pattern in a first region on a substrate;
forming a first metal-containing film in a second region on the substrate;
forming a second metal-containing film covering the first metal-containing film; and
forming a third metal-containing film covering the second metal-containing film,
wherein at least one of the first metal-containing film, the third metal-containing film, an interface between the first metal-containing film and the second metal-containing film, or an interface between the second metal-containing film and the third metal-containing film is formed using an organometallic compound of Formula 1 below: 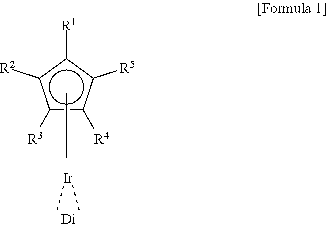
wherein, in Formula 1, R¹, R², R³, R⁴, and R⁵ are each independently a substituent including a heteroatom, hydrogen, an alkyl group having 1 to 10 carbon atoms, an alkenyl group having 2 to 10 carbon atoms, or an alkynyl group having 2 to 10 carbon atoms, and Di is a diene-based hydrocarbon, provided that a case where R¹, R², R³, R⁴, and R⁵ are all hydrogen or methyl groups is excluded or a case where one of R¹, R², R³, R⁴, and R⁵ is an alkyl group and the remaining ones are hydrogen is excluded.

18. The method of claim 17,
wherein the organometallic compound is liquid at room temperature.

19. The method of claim 17,
wherein the heteroatom is Si, O, N, P, or S.

20. The method of claim 17,
wherein at least one of the first metal-containing film, the third metal-containing film, the interface between the first metal-containing film and the second metal-containing film, and the interface between the second metal-containing film and the third metal-containing film, each of which is formed using the organometallic compound of Formula 1 above, is an iridium-containing film.
